(19) United States
(12) Patent Application Publication
(10) Pub. No.: US 2025/0028891 A1
(43) Pub. Date: Jan. 23, 2025

(54) CASCADE-BASED POWER DISSIPATION OPTIMIZATION METHOD AND SYSTEM FOR AMPLIFICATION CIRCUIT

(71) Applicant: Huazhong University of science and technology, Wuhan City (CN)

(72) Inventors: Xiaohu Ge, Wuhan City (CN); Xiaoxuan Peng, Wuhan City (CN); Qiang Li, Wuhan City (CN); Yi Zhong, Wuhan City (CN)

(21) Appl. No.: 18/483,625

(22) Filed: Oct. 10, 2023

(30) Foreign Application Priority Data
Jul. 6, 2023 (CN) 202310828103.6

(51) Int. Cl. G06F 30/373

(52) U.S. Cl. CPC G06F 30/373; H03F 1/0205

(57) ABSTRACT

A cascade-based power dissipation optimization method and system for an amplification circuit are provided. The method includes: S1, acquiring a relationship of power dissipation of an amplification circuit to input signal amplitudes and voltage gains by means of statistical analysis; and S2, designing an optimal cascade strategy for the amplification circuit according to the relationship of the power dissipation of the amplification circuit to the input signal amplitudes and the voltage gains, and adjusting the number of stages of the amplification circuit and a voltage gain of each stage of the amplification circuit so as to minimize total power dissipation of the amplification circuit.

### TECHNICAL FIELD

The present invention belongs to the technical field of analog circuits, and relates, more specifically, to a cascade-based power dissipation optimization method and system for an amplification circuit.

### BACKGROUND ART

As 5G mobile communication systems begin commercial deployment, global mobile data traffic presents an exponential growth trend, and power dissipation of wireless communication systems increases accordingly. Radio-frequency chains are one of the largest power dissipation sources in wireless communication systems, and the power dissipation thereof mainly comes from amplification circuits. Currently, low power dissipation of chips is achieved by shortening processes, reducing the number of contained electrons, reducing power supply voltages, and the like. However, the reduced number of electrons and the reduced power supply voltages result in performance deterioration of the amplification circuits. Therefore, how to achieve low power dissipation while fully utilizing the performance of transistors is a problem faced by transistor-based amplification circuits.

Since voltage gain is closely related to energy conversion loss of an amplification circuit, power dissipation of an amplification circuit can be effectively reduced by adjusting the voltage gain of each stage of the amplification circuit according to an appropriate cascade strategy to reduce energy conversion loss. In order to reduce the power dissipation of an amplification circuit, the relationship of the power dissipation of the amplification circuit to the number of stages and the voltage gain of each stage is discussed. The optimal cascade strategy of the amplification circuit needs to be designed according to different input voltage amplitudes and the total voltage gain so as to reduce the power dissipation of the amplification circuit, thereby facilitating green and healthy development of the information and communication technology industry.

### SUMMARY OF THE INVENTION

In view of the defects and improvement requirements of the prior art, provided in the present invention is a cascade-based power dissipation optimization method for an amplification circuit, the objective of which is to reduce power dissipation of the amplification circuit.

Provided in the present invention is a cascade-based power dissipation optimization method for an amplification circuit, the method comprising:
S1, acquiring a relationship of power dissipation of an amplification circuit to input signal amplitudes and voltage gains by means of statistical analysis; and
S2, designing an optimal cascade strategy for the amplification circuit according to the relationship of the power dissipation of the amplification circuit to the input signal amplitudes and the voltage gains, and adjusting the number of stages of the amplification circuit and a voltage gain of each stage of the amplification circuit so as to minimize total power dissipation of the amplification circuit.

Preferably, in step S1, the statistical analysis is performed with respect to the power dissipation of the amplification circuit for different input signal amplitudes and voltage gains, so as to acquire a function expression of the power dissipation of the amplification circuit in relation to the input signal amplitude and the voltage gain, and the voltage gain is expressed as:

$$G = {A}_{{V}_{out}} / {A}_{{V}_{in} ,}$$

where A_{V}_{ᵢₙ} represents the amplitude of an input signal Vᵢₙ, and A_{V}_{ₒᵤₜ} represents the amplitude of an output signal Vₒᵤₜ. The maximum operating condition of the amplification circuit is defined to be an operating condition in which the amplification circuit reaches the maximum voltage gain when the input signal amplitude and the power supply voltage are given and on condition that the waveform of the output signal is not distorted. If not indicated otherwise, the voltage gain of the amplification circuit in this method refers to the voltage gain of the amplification circuit in the maximum operating condition. Regression analysis is performed with respect to a statistical computation result of the power dissipation of the amplification circuit for different input signal amplitudes and voltage gains. The regression analysis result is defined as follows: P(A_{V}_{ᵢₙ}, G) represents the power dissipation when the input signal amplitude of the amplification circuit is A_{V}_{ᵢₙ} and a total voltage gain is G.

Beneficial effects: a power dissipation model of an amplification circuit is closely related to factors such as a specific material structure of the amplification circuit, environmental parameters, and the like, and it is difficult to establish a universal mathematical model that represents the power dissipation of the amplification circuit. A power dissipation model of an amplification circuit acquired by performing statistical analysis on measurement data of specific circuits is more practical, thereby greatly simplifying modeling processes and expanding the range of applications of the present invention. Considering that the power dissipation of the amplification circuit is closely related to the input signal amplitude and the voltage gain, and also considering, from a functional point of view, that the input signal amplitude and the voltage gain are important parameters of the amplification circuit, a power dissipation model acquired by performing regression analysis using the input signal amplitude and the voltage gain of the amplification circuit as variables can effectively calculate, according to specific functions to be implemented by the amplification circuit, the corresponding power dissipation, thereby providing a basis for designing the optimal cascade strategy for the amplification circuit.

Preferably, step S2 comprises:
performing cascade on the amplification circuit having a total voltage gain of G, so as to acquire a cascade amplification form consisting of n stages of cascaded amplification circuits in which a voltage gain of a stage-i amplification circuit is Gᵢ, wherein Πᵢ₌₁ⁿGᵢ=G, i=12, . . . , n, and n is the number of stages of the amplification circuit. For an amplification circuit of which the number of stages is K, i.e., a K-stage amplification circuit, power dissipation thereof satisfies:

$${P}_{sum}^{( K )} = P ( {A}_{{V}_{in}} , {G}_{1} ) + P ( {A}_{{V}_{in}} {G}_{1} , {G}_{2} ) + ⋯ + P ( {A}_{{V}_{in}} {\prod }_{i = 1}^{K - 2} {G}_{i} , {G}_{K - 1} ) + P ( {A}_{{V}_{in}} {\prod }_{i = 1}^{K - 1} {G}_{i} , G / {\prod }_{i = 1}^{K - 1} {G}_{i} )$$

wherein P(A_{V}_{ᵢₙ}, G) represents the power dissipation when the input signal amplitude of the amplification circuit is A_{V}_{ᵢₙ} and the voltage gain is G.

Beneficial effects: considering that there may be excessive energy dissipation for an existing amplification circuit performing single-stage amplification on an input signal, the present invention amplifies an input signal a plurality of times in stages, and adjusts the voltage gain of each stage of the amplification circuit to reduce power dissipation of the amplification circuit. During voltage amplification of the amplification circuit, energy conversion is not completely efficient, but instead, a certain amount of energy is lost in the form of heat. In addition, when the voltage gain increases, energy conversion loss in the circuit also increases accordingly. Therefore, the power dissipation of the amplification circuit can be further reduced by appropriately adjusting the number of stages of the amplification circuit and the voltage gain of each stage and by employing the optimal cascade strategy.

Preferably, when the K-stage amplification circuit has a given input signal amplitude A_{V}_{ᵢₙ} and a given total voltage gain G and has the minimum power dissipation, that is, when

$${min}_{{G}_{i} , i ∈ \{ 1 , 2 , … , K - 1 \}} \{ {P}_{s u m}^{( K )} \} ,$$

the voltage gain of each stage of the amplification circuit satisfies:

$$\frac{\partial {P}_{sum}^{( K )}}{\partial {G}_{i}} = 0$$

where Pₛᵤₘ^{(K)} represents the power dissipation of the K-stage amplification circuit, Gᵢ represents the voltage gain of the stage-i amplification circuit, and i=1, 2, . . . , K−1.

Beneficial effects: adjusting the voltage gain of each stage of the K-stage amplification circuit is equivalent to planning an energy conversion loss for each stage of the amplification circuit. The total energy conversion loss of the amplification circuit is minimized by appropriately adjusting the voltage gain of each stage of the amplification circuit. Since Gᵢ is a continuous variable, the process of planning each stage of the amplification circuit and appropriately allocating energy for each stage of the amplification circuit is smooth, and a power dissipation function of the K-stage amplification circuit is differentiable with respect to the voltage gain of each stage. The voltage gain of each stage corresponding to the minimum power dissipation of the K-stage amplification circuit can be acquired by setting a partial derivative of the power dissipation function of the K-stage amplification circuit with respect to the voltage gain of each stage to zero and performing calculation.

Preferably, selection of K., which is the optimal number of stages of the amplification circuit, satisfies: if Pₛᵤₘ⁽¹⁾≤Pₛᵤₘ⁽²⁾, then Kₘₐₓ=1, and if Pₛᵤₘ⁽¹⁾>Pₛᵤₘ⁽²⁾, then Kₘₐₓ satisfies Pₛᵤₘ^{(K}^{ₘₐₓ}⁾<Pₛᵤₘ^{(K}^{ₘₐₓ}⁻¹⁾ and Pₛᵤₘ^{(K}^{ₘₐₓ}⁾≤Pₛᵤₘ^{(K}^{ₘₐₓ}⁻¹⁾. Pₛᵤₘ^{(K)} represents the power dissipation of the amplification circuit of which the number of stages is K, Kₘₐₓ represents the optimal number of stages of the amplification circuit, and Pₛᵤₘ^{(K}^{ₘₐₓ}⁾ represents the power dissipation of the amplification circuit employing the optimal cascade strategy.

Beneficial effects: the selected optimal number of stages of the amplification circuit needs to minimize the total power dissipation of the amplification circuit. The cascade process of the amplification circuit reduces the energy conversion loss of each stage of the amplification circuit, but the increase in the number of stages of the amplification circuit causes corresponding device loss to increase. Therefore, increasing the number of stages of the amplification circuit does not lead to a continuous decrease in the total power dissipation of the amplification circuit. For a single-stage amplification circuit and a two-stage amplification circuit having the same input signal amplitude and total voltage gain, if power dissipation of the single-stage amplification circuit is less than or equal to power dissipation of the two-stage amplification circuit, then it is indicated that an increase in device loss caused by cascade is greater than a decrease in energy conversion loss, and the optimal number of stages of the amplification circuit is 1, that is, no cascade is performed. For a single-stage amplification circuit and a two-stage amplification circuit having the same input signal amplitude and total voltage gain, if power dissipation of the single-stage amplification circuit is greater than power dissipation of the two-stage amplification circuit, then it is indicated that the optimal number of stages of the amplification circuit is not 1, and K, which is the number of stages of the amplification circuit, can be increased continuously until Pₛᵤₘ^{(K)}<Pₛᵤₘ^{(K-1)} and Pₛᵤₘ^{(K)}≤Pₛᵤₘ^{(K+1)} are satisfied. That is, when the number of stages of the amplification circuit is increased, an increase in device loss caused by cascade is greater than or equal to a decrease in energy conversion loss, and when the number of stages is decreased, an increase in device loss caused by cascade is less than a decrease in energy conversion loss. In this case, the gain of cascade is maximized for the power dissipation of the amplification circuit, and the number of stages at the time is used as the optimal number of stages Kₘₐₓ.

Preferably, a power dissipation expression of the amplification circuit satisfies:

$$P ( {A}_{{V}_{in}} , G ) = {( 1 - α )}^{- 1} {P}_{effect} ( {A}_{{V}_{in}} , G )$$

wherein P_{effect}(A_{V}_{ᵢₙ}, G) represents power dissipation actually used for signal amplification when the input signal amplitude of the amplification circuit is A_{V}_{ᵢₙ} and the voltage gain is G, and α is an energy conversion loss coefficient, and represents the ratio of an energy loss not used for signal amplification but lost in the form of heat during signal amplification to the total power dissipation, and the energy conversion loss coefficient increases as the voltage gain increases.

Beneficial effects: the above expression shows the relationship between the total power dissipation of the amplification circuit during voltage amplification and the power dissipation actually used for signal amplification. It can be seen that the total power dissipation of the amplification circuit during voltage amplification is proportional to the power dissipation actually used for signal amplification, and a proportion coefficient is 1 minus the energy conversion loss coefficient. In addition, when the voltage gain increases, the energy conversion loss coefficient in the circuit also increases accordingly. Therefore, the energy conversion loss can be reduced by decreasing the voltage gain of the amplification circuit, thereby providing a theoretical basis for cascade-based optimization of the power dissipation of the amplification circuit.

Further provided in the present invention is a cascade-based power dissipation optimization system for an amplification circuit, comprising: a computer-readable storage medium and a processor,
the computer-readable storage medium being configured to store executable instructions, and
the processor being configured to read the executable instructions stored in the computer-readable storage medium, and to perform the above cascade-based power dissipation optimization method for an amplification circuit.

In general, the above technical solutions proposed in the present invention can achieve the following beneficial effects:

In the present invention, the amplification circuit is divided into stages, and the optimal cascade strategy is designed according to the input signal amplitude and the total voltage gain of the amplification circuit, so as to appropriately adjust the number of stages of the amplification circuit and the voltage gain of each stage, thereby reducing the energy conversion loss of the amplification circuit during voltage amplification, and optimizing the power dissipation of the amplification circuit.

### BRIEF DESCRIPTION OF THE DRAWINGS

FIG. 1 is a flowchart of a cascade-based power dissipation optimization method for an amplification circuit according to the present invention.

FIG. 2 is a flowchart of amplification circuit power dissipation modeling employing statistical analysis according to the present invention.

FIG. 3 is a schematic diagram of a cascade-based amplification circuit operation according to the present invention.

FIG. 4 is a flowchart of an optimal cascade strategy of an amplification circuit according to the present invention.

### DETAILED DESCRIPTION

In order for the purpose, technical solution, and advantages of the present invention to be clearer, the present invention is described in further detail below with reference to the accompanying drawings and embodiments. It should be understood that the specific embodiments described herein are only used to explain the present invention, but not to limit the present invention. In addition, the technical features involved in various embodiments of the present invention described below can be combined with one another as long as they do not constitute a conflict therebetween.

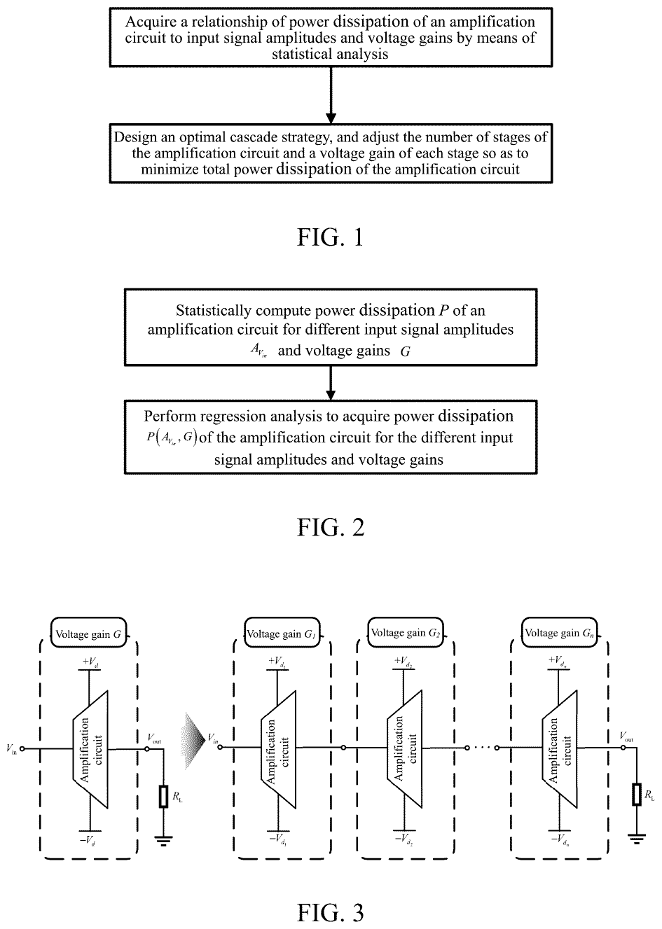

As shown in FIG. 1, a flowchart of a cascade-based power dissipation optimization method for an amplification circuit includes:
S1, statistically computing power dissipation of an amplification circuit for different input signal amplitudes and voltage gains, and performing regression analysis according to a statistical computation result, so as to acquire an amplification circuit power dissipation model.

For the amplification circuit power dissipation model, regression analysis is performed according to amplification circuit power dissipation sample values corresponding to the different input signal amplitudes and voltage gains, to acquire an amplification circuit power dissipation function expression using the input signal amplitude and the voltage gain as variables.

S2, designing an optimal cascade strategy for the amplification circuit according to the amplification circuit power dissipation model, and adjusting the number of stages of the amplification circuit and a voltage gain of each stage so that the optimal cascade strategy is satisfied.

The power dissipation of the amplification circuit can be effectively reduced by appropriately adjusting the number of stages of the amplification circuit and the voltage gain of each stage and by employing the optimal cascade strategy to reduce energy conversion loss.

FIG. 2 shows a flowchart of amplification circuit power dissipation modeling employing statistical analysis according to the present invention. The voltage gain G of the amplification circuit is calculated according to the amplitude A_{V}_{ᵢₙ} of an input signal Vₙ, and the amplitude A_{V}_{ₒᵤₜ} of an output signal Vₒᵤₜ of the amplification circuit, and the power dissipation P of the amplification circuit corresponding to different input signal amplitudes A_{V}_{ᵢₙ} and voltage gains G is acquired by means of testing, and then by using the same as samples, regression analysis is performed to acquire a function expression P(A_{V}_{ᵢₙ},G) of the power dissipation P of the amplification circuit in relation to the input signal amplitude A_{V}_{ᵢₙ} and the voltage gain G. Without loss of generality, the regression analysis result may be used as a power dissipation model of the amplification circuit.

FIG. 3 shows a schematic diagram of a cascade-based amplification circuit operation according to the present invention. Vᵢₙ and Vₒᵤₜ respectively represent input and output voltages, V_{d}_{ᵢ} represents a power supply voltage of the stage-i amplification circuit, and i=1, 2, . . . , n, and R_{L} is load resistance. Cascade is performed on the amplification circuit having a total voltage gain of G, so as to acquire a cascade amplification form consisting of n stages of cascaded amplification circuits in which a voltage gain of a stage-i amplification circuit is Gᵢ, wherein Πᵢ₌₁ⁿGᵢ=G, i=1, 2, . . . , n, and n is the number of stages of the amplification circuit. For an amplification circuit of which the number of stages is K, i.e., a K-stage amplification circuit, power dissipation thereof satisfies:

$${P}_{sum}^{( K )} = P ( {A}_{{V}_{in}} , {G}_{1} ) + P ( {A}_{{V}_{in}} {G}_{1} , {G}_{2} ) + ⋯ + P ( {A}_{{V}_{in}} {\prod }_{i = 1}^{K - 2} {G}_{i} , {G}_{K - 1} ) + P ( {A}_{{V}_{in}} {\prod }_{i = 1}^{K - 1} {G}_{i} , G / {\prod }_{i = 1}^{K - 1} {G}_{i} )$$

wherein P(A_{V}_{ᵢₙ}, G) represents the power dissipation when the input signal amplitude of the amplification circuit is A_{V}_{ᵢₙ} and the voltage gain is G.

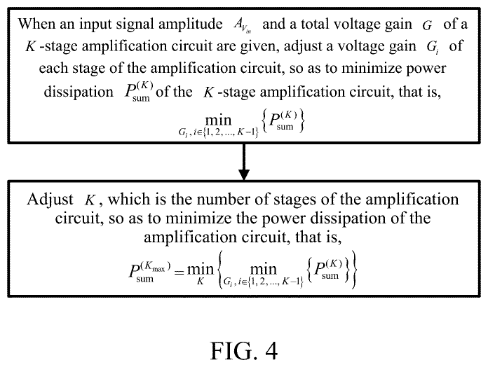

FIG. 4 shows a flowchart of an optimal cascade strategy of an amplification circuit according to the present invention. Since energy conversion loss occurs during voltage amplification of the amplification circuit, and since energy conversion loss in the circuit increases along with an increase in the voltage gain, the energy conversion loss can be reduced by decreasing the voltage gain of the amplification circuit by means of cascade. However, while the cascade process of the amplification circuit reduces the energy conversion loss of each stage of the amplification circuit, the increase in the number of stages of the amplification circuit causes corresponding device loss to increase. Therefore, increasing the number of stages of the amplification circuit does not lead to a continuous decrease in the total power dissipation of the amplification circuit. The number of stages of the amplification circuit and the voltage gain of each stage need to be adjusted appropriately to design the optimal cascade strategy for the amplification circuit.

For the K-stage amplification circuit, adjusting the voltage gain of each stage is equivalent to planning energy conversion loss of each stage of the amplification circuit. The total energy conversion loss of the amplification circuit is minimized by appropriately adjusting the voltage gain of each stage of the amplification circuit. Since the voltage gain Gᵢ of the stage-i amplification circuit is a continuous variable, the process of planning each stage of the amplification circuit and appropriately allocating energy for each stage of the amplification circuit is smooth, and a power dissipation function of the K-stage amplification circuit is differentiable with respect to the voltage gain of each stage. The voltage gain of each stage corresponding to the minimum power dissipation of the K-stage amplification circuit can be acquired by setting a partial derivative of the power dissipation function of the K-stage amplification circuit with respect to the voltage gain of each stage to zero and performing calculation, that is,

$${min}_{{G}_{i} , i ∈ \{ 1 , 2 , … , K - 1 \}} \{ {P}_{s u m}^{( K )} \} .$$

For the K-stage amplification circuit satisfying

$${min}_{{G}_{i} , i ∈ \{ 1 , 2 , … , K - 1 \}} \{ {P}_{s u m}^{( K )} \}$$

and having the same input signal amplitude and total voltage gain, a balance between the decrease in the energy conversion loss and the increase in the device loss needs to be achieved, so as to acquire the optimal cascade strategy. For K=1 and K=2, that is, for a single-stage amplification circuit and a two-stage amplification circuit, if power dissipation of the single-stage amplification circuit is less than or equal to power dissipation of the two-stage amplification circuit, then it is indicated that an increase in device loss caused by cascade is greater than a decrease in energy conversion loss, and the optimal number of stages of the amplification circuit is 1, that is, no cascade is performed. If power dissipation of the single-stage amplification circuit is greater than power dissipation of the two-stage amplification circuit, then it is indicated that the optimal number of stages of the amplification circuit is not 1, and K, which is the number of stages of the amplification circuit, can be increased continuously until Pₛᵤₘ^{(K)}<Pₛᵤₘ^{(K-1)} and Pₛᵤₘ^{(K)}≤Pₛᵤₘ^{(K+1)} are satisfied. That is, when the number of stages of the amplification circuit is increased, an increase in device loss caused by cascade is greater than or equal to a decrease in energy conversion loss, and when the number of stages is decreased, an increase in device loss caused by cascade is less than a decrease in energy conversion loss. In this case, the gain of cascade is maximized for the power dissipation of the amplification circuit, the number of stages at the time is used as the optimal number of stages Kₘₐₓ, and the power dissipation of the amplification circuit satisfies

$${min}_{K} \{ {min}_{{G}_{i} , i ∈ \{ 1 , 2 , … , K - 1 \}} \{ {P}_{sum}^{( K )} \} \} .$$

It can be easily understood by a person skilled in the art that the foregoing description is only preferred embodiments of the present invention and is not intended to limit the present invention. Any modifications, identical replacements, improvements and so on that are within the spirit and principle of the present invention should be included in the scope of protection of the present invention.

1. A cascade-based power dissipation optimization method for an amplification circuit, characterized by comprising:
S1, acquiring a relationship of power dissipation of an amplification circuit to input signal amplitudes and voltage gains by means of statistical analysis; and
S2, designing an optimal cascade strategy for the amplification circuit according to the relationship of the power dissipation of the amplification circuit to the input signal amplitudes and the voltage gains, and adjusting the number of stages of the amplification circuit and a voltage gain of each stage of the amplification circuit so as to minimize total power dissipation of the amplification circuit.

2. The method according to claim 1, wherein in step S1, the statistical analysis is performed with respect to the power dissipation of the amplification circuit for different input signal amplitudes and voltage gains, so as to acquire a function expression P(A_{V}_{ᵢₙ}, G) of the power dissipation of the amplification circuit in relation to the input signal amplitude and the voltage gain, where G is the voltage gain, and G=A_{V}_{ₒᵤₜ}/A_{V}_{ᵢₙ}, A_{V}_{ᵢₙ} representing the amplitude of an input signal Vᵢₙ, and A_{V}_{ₒᵤₜ} representing the amplitude of an output signal Vₒᵤₜ.

3. The method according to claim 2, wherein step S2 comprises:
performing cascade on the amplification circuit having a total voltage gain of G, so as to acquire a cascade amplification form consisting of n stages of cascaded amplification circuits in which a voltage gain of a stage-i amplification circuit is Gᵢ, wherein Πᵢ₌₁ⁿ=G, i=1, 2, . . . , n, and n is the number of stages of the amplification circuit, wherein for an amplification circuit of which the number of stages is K, i.e., a K-stage amplification circuit, power dissipation thereof satisfies
$${P}_{sum}^{( K )} = P ( {A}_{{V}_{in}} , {G}_{1} ) + P ( {A}_{{V}_{in}} {G}_{1} , {G}_{2} ) + ⋯ + P ( {A}_{{V}_{in}} {\prod }_{i = 1}^{K - 2} {G}_{i} , {G}_{K - 1} ) + P ( {A}_{{V}_{in}} {\prod }_{i = 1}^{K - 1} {G}_{i} , G / {\prod }_{i = 1}^{K - 1} {G}_{i} ) ,$$
and the voltage gain G, of each stage of the amplification circuit is adjusted so as to minimize the power dissipation of the K-stage amplification circuit.

4. The method according to claim 3, wherein when the K-stage amplification circuit has a given input signal amplitude A_{V}_{ᵢₙ} and a given total voltage gain G and has the minimum power dissipation, that is, when
$${min}_{{G}_{i} , i ∈ \{ 1 , 2 , … , K - 1 \}} \{ {P}_{s u m}^{( K )} \} ,$$
the voltage gain of each stage of the amplification circuit satisfies:
$$\frac{\partial {P}_{sum}^{( K )}}{\partial {G}_{i}} = 0$$
where Pₛᵤₘ^{(K)} represents the power dissipation of the K-stage amplification circuit, G, represents the voltage gain of the stage-i amplification circuit, and i=1, 2, . . . , K−1.

5. The method according to claim 3, wherein selection of Kₘₐₓ, which is the optimal number of stages of the amplification circuit, satisfies:
if Pₛᵤₘ⁽¹⁾≤Pₛᵤₘ⁽²⁾, then Kₘₐₓ=1, and
if Pₛᵤₘ⁽¹⁾>Pₛᵤₘ⁽²⁾, then Kₘₐₓ satisfies Pₛᵤₘ^{(K}^{ₛᵤₘ}⁾<Pₛᵤₘ^{(K}^{ₛᵤₘ}⁻¹⁾ and Pₛᵤₘ^{(K}^{ₛᵤₘ}⁾≤Pₛᵤₘ^{(K}^{ₛᵤₘ}⁻¹⁾,
where Kₘₐₓ represents the optimal number of stages of the amplification circuit, Pₛᵤₘ^{(K)} represents the power dissipation of the K-stage amplification circuit, and Pₛᵤₘ^{(K}^{ₛᵤₘ}⁾ represents the power dissipation of the amplification circuit employing the optimal cascade strategy.

6. The method according to claim 2, wherein the power dissipation of the amplification circuit satisfies:
$$P ( {A}_{{V}_{in}} , G ) = {( 1 - α )}^{- 1} {P}_{effect} ( {A}_{{V}_{in}} , G )$$
wherein P_{effect}(A_{V}_{ᵢₙ},G) represents power dissipation actually used for signal amplification when the input signal amplitude of the amplification circuit is A_{V}_{ᵢₙ} and the voltage gain is G, and α is an energy conversion loss coefficient, and represents the ratio of an energy loss not used for signal amplification but lost in the form of heat during signal amplification to the total power dissipation, and the energy conversion loss coefficient increases as the voltage gain increases.

7. A cascade-based power dissipation optimization system for an amplification circuit, characterized by comprising: a computer-readable storage medium and a processor,
the computer-readable storage medium being configured to store executable instructions, and
the processor being configured to read the executable instructions stored in the computer-readable storage medium, and to perform the cascade-based power dissipation optimization method for an amplification circuit according to claim 1.
